(19) United States
(12) Patent Application Publication
(10) Pub. No.: US 2018/0040508 A1
(43) Pub. Date: Feb. 8, 2018

(54) TFT STRUCTURE AND REPAIR METHOD THEREOF, GOA CIRCUIT

(71) Applicant: Shenzhen China Star Optoelectronics Technology Co., Ltd., Shenzhen City (CN)

(72) Inventor: Xiangdeng Que, Shenzhen City (CN)

(21) Appl. No.: 15/025,893

(22) PCT Filed: Feb. 25, 2016
(86) PCT No.: PCT/CN2016/074499

§ 371 Date: Mar. 30, 2016

(30) Foreign Application Priority Data
Jan. 12, 2016 (CN) 201610018659.9

(51) Int. Cl. H01L 21/768; G09G 3/22; H01L 29/786

(52) U.S. Cl. CPC H01L 21/76868; H01L 29/786; G09G 3/22

(57) ABSTRACT

The present invention provides a TFT structure and a repair method thereof, a GOA circuit. The TFT structure and the repair method thereof includes a source (10) having a plurality of independent U shape source branches (101). The drain (20) comprises a plurality strip drain branches (201). Each independent U shape source branch (101) is solely connected to a first metal line (30) with a connection part (103), and all the plurality of strip drain branches (201) are electrically coupled to a second metal line (40). The respective independent U shape source branches (101) and the corresponding strip drain branches (201) construct a plurality of independent source-drain conduction channels; as some independent U shape source branch (101) and the corresponding strip drain branch (201) are detected having a defect, the repair can be implemented by disconnecting the independent U shape source branch (101) and disconnecting the corresponding strip drain branch (201).

### FIELD OF THE INVENTION

The present invention relates to a display technology field, and more particularly to a TFT structure and a repair method thereof, a GOA circuit.

### BACKGROUND OF THE INVENTION

The Liquid Crystal Display (LCD) possesses advantages of thin body, power saving and no radiation to be widely used in many application scope, such as LCD TV, mobile phone, personal digital assistant (PDA), digital camera, notebook, laptop, and dominates the flat panel display field.

Most of the liquid crystal displays on the present market are backlight type liquid crystal displays, which comprise a liquid crystal display panel and a backlight module. The working principle of the liquid crystal display panel is that the Liquid Crystal is injected between the Thin Film Transistor Array Substrate (TFT array substrate) and the Color Filter (CF). The light of backlight module is refracted to generate images by applying driving voltages to the two substrates for controlling the rotations of the liquid crystal molecules.

The Active Matrix Liquid Crystal Display (AMLCD) is the most common liquid crystal display at present. The Active Matrix Liquid Crystal Display comprises a plurality of pixels, and each pixel is controlled by one Thin Film Transistor (TFT). The gate of the TFT is coupled to the scan line extending along the horizontal direction. The drain of the TFT is coupled to the data line extending along the vertical direction. The source is coupled to the corresponding pixel electrode. When a sufficient positive voltage is applied to some scan line in the horizontal direction, all the TFT coupled to the scan line will be activated to write the data signal loaded in the data line into the pixel electrodes and thus to show images to control the transmittances of different liquid crystals to achieve the effect of controlling colors.

The driving of the level scan line (i.e. the gate driving) in the present active matrix liquid crystal display is initially accomplished by the external Integrated Circuit (IC). The external IC can control the charge and discharge stage by stage of the level scan lines of respective stages. The GOA technology, i.e. the Gate Driver on Array technology can utilize the array manufacture processes of the liquid crystal display panel to manufacture the driving circuit of the level scan lines on the substrate around the active area, to replace the external IC for accomplishing the driving of the level scan lines. The GOA technology can reduce the bonding procedure of the external IC and has potential to raise the productivity and lower the production cost. Meanwhile, it can make the liquid crystal display panel more suitable to the narrow frame design of display products.

The GOA circuit comprises a plurality of TFTs. FIG. 1 shows a TFT structure in a GOA circuit according to prior art, comprising a comb source constructed by a plurality of U shape source branches 11 connected with one another, and a drain constructed by strip drain branches 12 of the same amount as the plurality of U shape source branches 11. One strip drain branch 12 is set to correspond to the opening of one U shape source branch 11. The U shape source branch 11 comprises a transverse part 111 and two longitudinal parts 112 perpendicularly connected to the transverse part 111. The transverse parts 111 of the plurality of U shape source branches 11 are connected to be one body. The two adjacent U shape source branches 11 share one longitudinal part 112; the plurality of strip drain branches 12 are connected to the same metal line, and the all the plurality of U shape source branches 11 are connected to another metal line through the same connection part 113. In the TFT structure shown in FIG. 1, as the defect appears in one U shape source branch 11 and the corresponding strip drain branch 12, it results in the electrical failure of the entire TFT and cannot be repaired. Thus, the logic error happens in the GOA circuit utilizing the TFT structure, and even the waste of the entire panel.

### SUMMARY OF THE INVENTION

An objective of the present invention is to provide a TFT substrate structure, which is easy to repair.

Another objective of the present invention is to provide a repair method of a TFT, which can effectively repair the defect of the TFT and raise the repair success rate.

Another objective of the present invention is to provide a GOA circuit, which can promote the manufacture yield of the GOA circuit and reduce the production cost of the GOA circuit.

For realizing the aforesaid objectives, the present invention provides a TFT structure, comprising a source, a drain oppositely located to the source, and a gate, located above or under the source and the drain, and mutually isolated with the source and the drain;

the source comprises a plurality of U shape source branches, spaced and aligned along a first direction, and the drain comprises a plurality of strip drain branches, spaced and aligned along the first direction;

one strip drain branch is located inside an opening of one independent U shape source branch;

each independent U shape source branch is solely connected to a first metal line with a connection part; all the plurality of strip drain branches are electrically coupled to a second metal line.

Each independent U shape source branch comprises a transverse part extending along the first direction, and two longitudinal parts perpendicularly connected to two ends of the transverse part.

Each connection part is drew out from the transverse part of the independent U shape source branch corresponding thereto, and extends to the first metal line to achieve a sole connection of each independent U shape source branch and the first metal line.

The strip drain branch is parallel with the longitudinal part of the independent U shape source branch.

The TFT structure further comprises an active layer located under the source and the drain.

The present invention further provides a repair method of a TFT, comprising steps of:

step 1, providing a TFT, comprising a source, a drain oppositely located to the source, and a gate, located above or under the source and the drain, and mutually isolated with the source and the drain;

the source comprises a plurality of U shape source branches, spaced and aligned along a first direction, and the drain comprises a plurality of strip drain branches, spaced and aligned along the first direction;

one strip drain branch is located inside an opening of one independent U shape source branch;

each independent U shape source branch is solely connected to a first metal line with a connection part; all the plurality of strip drain branches are electrically coupled to a second metal line;

step 2, detecting whether the respective independent U shape source branches and the corresponding strip drain branches in the TFT have defects or not to find out the independent U shape source branch and the corresponding strip drain branch having a defect;

step 3, cutting a connection between the independent U shape source branch having the defect and the first metal line, and cutting a connection between the corresponding strip drain branch and the second metal line.

Each independent U shape source branch comprises a transverse part extending along the first direction, and two longitudinal parts perpendicularly connected to two ends of the transverse part;

The strip drain branch is parallel with the longitudinal part of the independent U shape source branch.

Each connection part is drew out from the transverse part of the independent U shape source branch corresponding thereto, and extends to the first metal line to achieve a sole connection of each independent U shape source branch and the first metal line;

in the step 3, cutting the connection between the independent U shape source branch having the defect and the first metal line is to cut the corresponding connection part.

An active layer is further located under the source and the drain.

The present invention further provides a GOA circuit, comprising the aforesaid TFT structure.

The benefits of the present invention are: the present invention provides a TFT structure and a repair method thereof. The TFT comprises a source having a plurality of U shape source branches, spaced and aligned along a first direction, and a drain having a plurality of strip drain branches, spaced and aligned along the first direction. Each independent U shape source branch is solely connected to a first metal line with a connection part, and all the plurality of strip drain branches are electrically coupled to a second metal line. The respective independent U shape source branches and the corresponding strip drain branches construct a plurality of independent source-drain conduction channels, and the respective independent source-drain conduction channels do not influence with one another. As some independent U shape source branch and the corresponding strip drain branch is detected having a defect, the repair can be implemented by cutting the connection between the independent U shape source branch and the first metal line, and cutting the connection between corresponding strip drain branch and the second metal line. Namely, the source-drain conduction channel having a defect is cut, and other source-drain conduction channels can remain working normally. Accordingly, the defect of the TFT can be effectively repaired to raise the repair success rate. The present invention provides a GOA circuit, comprising the aforesaid TFT structure, can promote the manufacture yield of the GOA circuit and reduce the production cost of the GOA circuit.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a diagram of a TFT structure in a GOA circuit according to prior art;

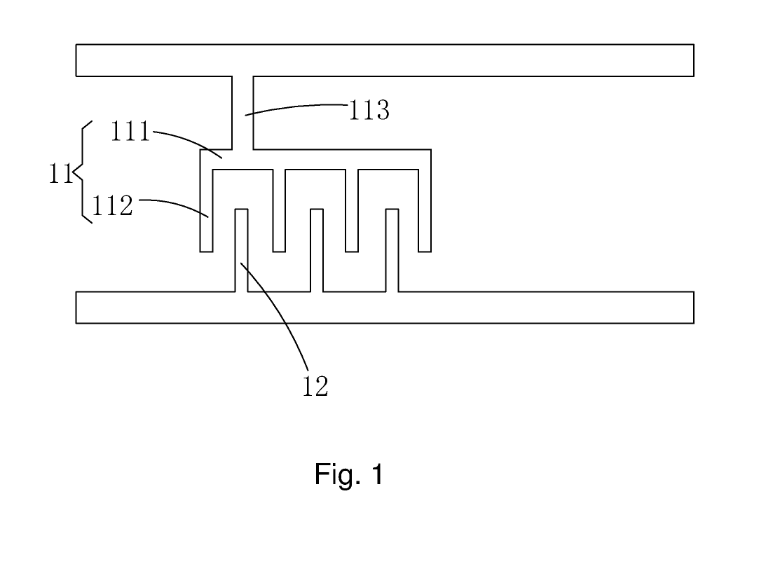

FIG. 2 is a diagram of a TFT structure of the present invention;

FIG. 3 is a flowchart of a repair method of a TFT according to the present invention;

FIG. 4 is a diagram of the step 3 of the repair method of the TFT according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

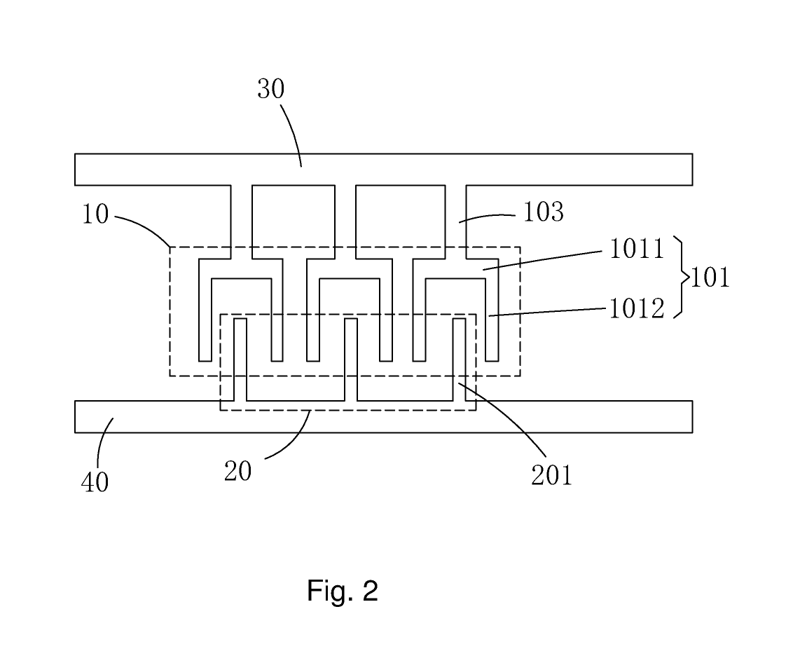

Please refer to FIG. 2. The present invention first provides a TFT structure, comprising a source 10, a drain 20 oppositely located to the source 10, and a gate (not shown in figure), located above or under the source 10 and the drain 20, and mutually isolated with the source 10 and the drain 20.

The source 10 comprises a plurality of U shape source branches 101, spaced and aligned along a first direction, and the drain 20 comprises a plurality of strip drain branches 201, spaced and aligned along the first direction. One strip drain branch 201 is located inside an opening of one independent U shape source branch 101.

Each independent U shape source branch 101 is solely connected to a first metal line 30 with a connection part 103; all the plurality of strip drain branches 201 are electrically coupled to a second metal line 40.

Specifically, each independent U shape source branch 101 comprises a transverse part 1011 extending along the first direction, and two longitudinal parts 1012 perpendicularly connected to two ends of the transverse part 1011. The strip drain branch 201 is parallel with the longitudinal part 1012 of the independent U shape source branch 101.

Each connection part 103 is drew out from the transverse part 1011 of the independent U shape source branch 101 corresponding thereto, and extends to the first metal line 30 to achieve a sole connection of each independent U shape source branch 101 and the first metal line 30.

Preferably, the first metal line 30 and the second metal line 40 are mutually parallel and spaced, and the first direction is the horizontal direction, and the transverse part 1011 extends horizontally, and the longitudinal part 1012 extends vertically, and the first and second metal lines 30, 40 extends horizontally, and the strip drain branch 201 extends vertically.

The TFT structure further comprises an active layer (not shown in figure) located under the source 10 and the drain 20.

Selectably, the TFT structure is a bottom gate type or a top gate type: as the TFT structure is the bottom gate type, the gate is under the source 10 and the drain 20; as the TFT structure is the top gate type, the gate is above the source 10 and the drain 20.

Selectably, material of the source 10, the drain 20 and the gate is a stack combination of one or more of copper, aluminum, molybdenum and titanium.

Selectably, the active layer is N-type doped or P-type doped.

In the aforesaid TFT structure, the gate is employed to receive a switch signal to control on and off of all the independent U shape source branches 101 and the corresponding strip drain branches 201. Significantly, the respective independent U shape source branches 101 and the corresponding strip drain branches 201 construct a plurality of independent source-drain conduction channels, and the disconnection of any one of the source-drain conduction channels does not influence the other source-drain conduction channels. Thus, as some independent U shape source branch 101 and the corresponding strip drain branch 201 are detected having a defect (such as short circuit), the repair can be implemented by cutting the connection between the independent U shape source branch 101 and the first metal line 30, and cutting the connection between corresponding strip drain branch 201 and the second metal line 40. Namely, the source-drain conduction channel having a defect is disconnected, and other source-drain conduction channels can remain working normally. Therefore, the TFT structure of the present invention can be easily repaired.

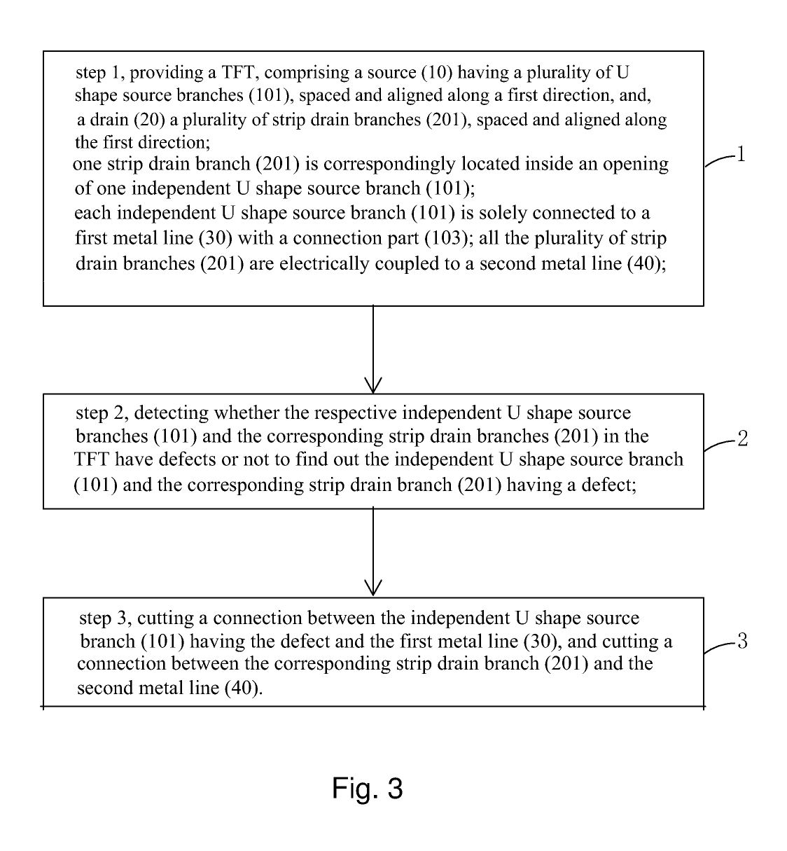

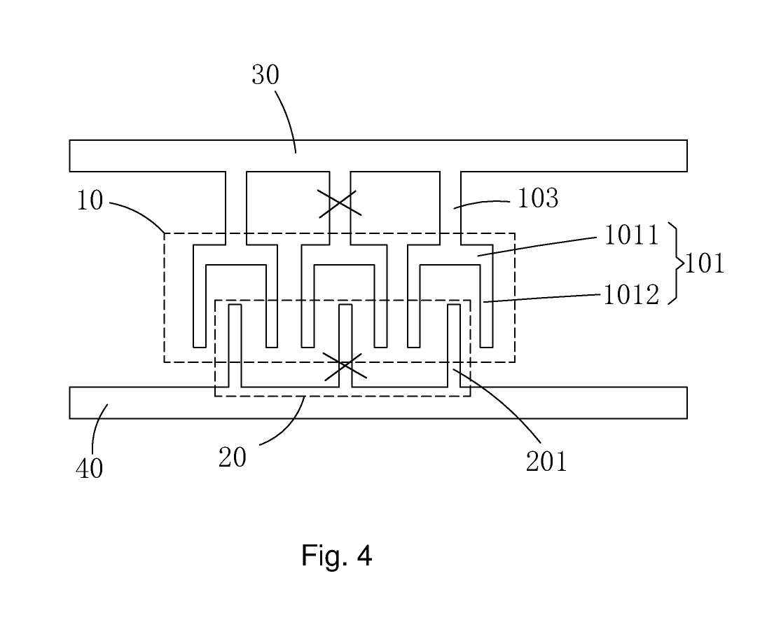

Please refer to FIG. 3 combining with FIG. 2, FIG. 4, the present invention further provides a repair method of a TFT, comprising steps of:

step 1, providing a TFT shown in FIG. 2. The description of the TFT structure is not repeated here.

step 2, detecting whether the respective independent U shape source branches 101 and the corresponding strip drain branches 201 in the TFT have defects or not to find out the independent U shape source branch 101 and the corresponding strip drain branch 201 having a defect.

step 3, as shown in FIG. 4, cutting a connection between the independent U shape source branch 101 having the defect and the first metal line 30, and cutting a connection between the corresponding strip drain branch 201 and the second metal line 40.

Specifically, cutting the connection between the independent U shape source branch 101 having the defect and the first metal line 30 is to cut the corresponding connection part 103.

In the repair method of the TFT according to the present invention, the TFT comprises a source 10 having a plurality of U shape source branches 101, spaced and aligned along a first direction, and a drain 20 having a plurality of strip drain branches 201, spaced and aligned along the first direction. Each independent U shape source branch 101 is solely connected to a first metal line 30 with a connection part 103, and all the plurality of strip drain branches 201 are electrically coupled to a second metal line 40. The respective independent U shape source branches 101 and the corresponding strip drain branches 201 construct a plurality of independent source-drain conduction channels, and the respective independent source-drain conduction channels do not influence with one another. As some independent U shape source branch 101 and the corresponding strip drain branch 201 are detected having a defect, the repair can be implemented by cutting the connection between the independent U shape source branch 101 and the first metal line 30, and cutting the connection between corresponding strip drain branch 201 and the second metal line 40. Namely, the source-drain conduction channel having a defect is cut, and other source-drain conduction channels can remain working normally. Accordingly, the defect of the TFT can be effectively repaired to raise the repair success rate.

The present invention further provides a GOA circuit, comprising the TFT structure shown in FIG. 2. Compared with the GOA circuit of prior art utilizing the TFT structure which cannot repair, the structure can promote the manufacture yield of the GOA circuit and reduce the production cost of the GOA circuit.

In conclusion, in the TFT structure and a repair method thereof according to the present invention, the TFT comprises a source having a plurality of U shape source branches, spaced and aligned along a first direction, and a drain having a plurality of strip drain branches, spaced and aligned along the first direction. Each independent U shape source branch is solely connected to a first metal line with a connection part, and all the plurality of strip drain branches are electrically coupled to a second metal line. The respective independent U shape source branches and the corresponding strip drain branches construct a plurality of independent source-drain conduction channels, and the respective independent source-drain conduction channels do not influence with one another. As some independent U shape source branch and the corresponding strip drain branch is detected having a defect, the repair can be implemented by cutting the connection between the independent U shape source branch and the first metal line, and cutting the connection between corresponding strip drain branch and the second metal line. Namely, the source-drain conduction channel having a defect is cut, and other source-drain conduction channels can remain working normally. Accordingly, the defect of the TFT can be effectively repaired to raise the repair success rate. The GOA circuit of the present invention comprises the aforesaid TFT structure, and can promote the manufacture yield of the GOA circuit and reduce the production cost of the GOA circuit.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A TFT structure, comprising a source, a drain oppositely located to the source, and a gate, located above or under the source and the drain, and mutually isolated with the source and the drain;
the source comprises a plurality of U shape source branches, spaced and aligned along a first direction, and the drain comprises a plurality of strip drain branches, spaced and aligned along the first direction;
one strip drain branch is located inside an opening of one independent U shape source branch;
each independent U shape source branch is solely connected to a first metal line with a connection part; all the plurality of strip drain branches are electrically coupled to a second metal line.

2. The TFT structure according to claim 1, wherein each independent U shape source branch comprises a transverse part extending along the first direction, and two longitudinal parts perpendicularly connected to two ends of the transverse part.

3. The TFT structure according to claim 2, wherein each connection part is drew out from the transverse part of the independent U shape source branch corresponding thereto, and extends to the first metal line to achieve a sole connection of each independent U shape source branch and the first metal line.

4. The TFT structure according to claim 2, wherein the strip drain branch is parallel with the longitudinal part of the independent U shape source branch.

5. The TFT structure according to claim 1, further comprising an active layer located under the source and the drain.

6. A repair method of a TFT, comprising steps of:
step 1, providing a TFT, comprising a source, a drain oppositely located to the source, and a gate, located above or under the source and the drain, and mutually isolated with the source and the drain;
the source comprises a plurality of U shape source branches, spaced and aligned along a first direction, and the drain comprises a plurality of strip drain branches, spaced and aligned along the first direction;
one strip drain branch is located inside an opening of one independent U shape source branch;
each independent U shape source branch is solely connected to a first metal line with a connection part; all the plurality of strip drain branches are electrically coupled to a second metal line;
step 2, detecting whether the respective independent U shape source branches and the corresponding strip drain branches in the TFT have defects or not to find out the independent U shape source branch and the corresponding strip drain branch having a defect;
step 3, cutting a connection between the independent U shape source branch having the defect and the first metal line, and cutting a connection between the corresponding strip drain branch and the second metal line.

7. The repair method of the TFT according to claim 6, wherein each independent U shape source branch comprises a transverse part extending along the first direction, and two longitudinal parts perpendicularly connected to two ends of the transverse part;
The strip drain branch is parallel with the longitudinal part of the independent U shape source branch.

8. The repair method of the TFT according to claim 7, wherein each connection part is drew out from the transverse part of the independent U shape source branch corresponding thereto, and extends to the first metal line to achieve a sole connection of each independent U shape source branch and the first metal line;
in the step 3, cutting the connection between the independent U shape source branch having the defect and the first metal line is to cut the corresponding connection part.

9. The repair method of the TFT according to claim 6, wherein an active layer is further located under the source and the drain.

10. A GOA circuit, comprising a TFT structure, and the TFT structure comprises a source, a drain oppositely located to the source, and a gate, located above or under the source and the drain, and mutually isolated with the source and the drain;
the source comprises a plurality of U shape source branches, spaced and aligned along a first direction, and the drain comprises a plurality of strip drain branches, spaced and aligned along the first direction;
one strip drain branch is located inside an opening of one independent U shape source branch;
each independent U shape source branch is solely connected to a first metal line with a connection part; all the plurality of strip drain branches are electrically coupled to a second metal line.

11. The GOA circuit according to claim 10, wherein each independent U shape source branch comprises a transverse part extending along the first direction, and two longitudinal parts perpendicularly connected to two ends of the transverse part.

12. The GOA circuit according to claim 11, wherein each connection part is drew out from the transverse part of the independent U shape source branch corresponding thereto, and extends to the first metal line to achieve a sole connection of each independent U shape source branch and the first metal line.

13. The GOA circuit according to claim 11, wherein the strip drain branch is parallel with the longitudinal part of the independent U shape source branch.

14. The GOA circuit according to claim 10, further comprising an active layer located under the source and the drain.
